(19) United States
(12) Patent Application Publication
(10) Pub. No.: US 2018/0375003 A1
(43) Pub. Date: Dec. 27, 2018

(54) LED LAMP WITH SLOW DECAY RED PHOSPHOR RESULTING IN CCT VARIATION WITH LIGHT OUTPUT

(71) Applicant: PHILIPS LIGHTING HOLDING B.V., EINDHOVEN (NL)

(72) Inventors: Martinus Petrus Joseph PEETERS, EINDHOVEN (NL); Malgorzata PERZ, EINDHOVEN (NL); Rémy Cyrille BROERSMA, EINDHOVEN (NL); Dragan SEKULOVSKI, EINDHOVEN (NL); René Theodorus WEGH, EINDHOVEN (NL)

(21) Appl. No.: 15/741,332

(22) PCT Filed: Jun. 22, 2016
(86) PCT No.: PCT/EP2016/064427

§ 371 Date: Jan. 2, 2018

(30) Foreign Application Priority Data
Jul. 2, 2015 (EP) 15175060.1

(51) Int. Cl. H01L 33/50; H05B 33/08; C09K 11/77; F21V 9/08

(52) U.S. Cl. CPC H01L 33/504; H05B 33/086; H05B 33/14; F21V 9/08; C09K 11/7779

(57) ABSTRACT

The invention provides a lighting device (100) comprising a) a light source (10) configured to provide blue light source light (11), b) a first luminescent material (210) configured to convert at least part of the light source light (11) into first luminescent material light (211) with light intensity in one or more of the green spectral region and yellow spectral region, c) a second luminescent material (220) configured to convert (i) at least part of the light source light (11), or (ii) at least part of the light light (11) and at least part of the first luminescent material light (221) with light intensity in the red spectral region, and d) a light exit face (110), wherein the lighting device (100) is configured to provide lighting device light (101) downstream from said light exit face (110), wherein the lighting device light (101) comprises one or more of said light source light (11), said first luminescent material light (211), and said second luminescent material light (221), and wherein the second luminescent material (220) is configured to be at least partly saturated with (i) light source light (11), or (ii) light source light (11) and first luminescent material light (211), at or above at least 50% of nominal operation power of the lighting device (100).

### FIELD OF THE INVENTION

The invention relates to a lighting device and to a method for providing (white) light.

### BACKGROUND OF THE INVENTION

Light sources with modifiable colors are known in the art. WO2007020556, for instance, describes a light source, which produces light leaving the light source with modifiable colors, with at least one light emitting diode for emitting primary radiation comprising a layer connected with said diode, wherein said layer includes at least one luminescent material for converting the primary radiation into a secondary radiation, a switching device driving the diode with a pulse-shaped current in order to provide a light, which includes the primary and/or the secondary radiation, in such a way that each of luminosity of the light and the color are changeable independently.

### SUMMARY OF THE INVENTION

For LED lighting, tunable white (color temperature variation along the BBL) is a desired feature. Several options seem possible to address this desired.

For instance, it may be an option to use moveable elements, for instance, where the physical position of the phosphor (or luminescent material) with respect to the LED is varied. However, moveable elements may not always be desired. Another option may be to use different LEDs, and to control these independently. However, this may be accompanied with more electronic circuitry, which may also not always be desired. The use of long decay phosphors might also be a possible route to diminish the stroboscopic effect visible for LEDs driven on a (rectified) AC input or on a tapped-linear driver. Some energy can be stored in the phosphor, enabling emission of light in the off-period of the pump source. Disadvantage of this solution seems that it is the inevitable that a color point variation with drive current occurs: some of the phosphor should be saturated (otherwise no light can be emitted in the off-period) but the amount of saturation depends on the flux density of the pump. The saturated phosphor, no longer absorbs light. As a consequence the ‘amount of active phosphor’ on the LED depends on the flux density, resulting in a strong color point shift (possible exception: UV-based LED sources).

Hence, it is an aspect of the invention to provide an alternative lighting device, which preferably further at least partly obviates one or more of above-described drawbacks. It is also an aspect of the invention to provide an alternative lighting method, which preferably further also at least partly obviates one or more of above-described drawbacks.

It is herein especially proposed to use a blue LED with a yellow and/or green luminescent material as well as a red luminescent material to provide white light. The red luminescent material, or at least part thereof, is over at least part of the power range of the blue LED in saturation. When saturated, the luminescence intensity of the red luminescent material is not linearly proportional to the power anymore. Hence, in this way a shift in the color point can be achieved by varying the power. It surprisingly appeared that a color point shift may follow very well the black body locus (BBL), comparable to halogen lamps. Hence, especially herein a white light emitting device is proposed with a tunable correlated color temperature (CCT) that is relatively simple and does not need complicated electronics.

Especially, by using a slow red phosphor, the amount of red phosphor able to absorb light depends on the flux density of the LED. At a low flux density, the amount of red phosphor that is saturated is small (or even zero); this will result in a low CCT. At a high flux density, the amount of red phosphor that is saturated increases, resulting in a decreased red contribution and thus a higher CCT. The color temperature of the lamp automatically changes with flux. Both the low and high CCT light is emitted from the same surface (no problems with color mixing). Especially, the excitation spectrum of the red phosphor should be broad such that the red phosphor is excited by both blue and yellow light in order to change both the blue and yellow emission with saturation. Then upon changing the flux density the ratio between red and (yellow+blue) light will change, which is a change between cold and warm white light. Saturation of the phosphor does not lead to extra energy loss (phosphor does not quench, just does not absorb light anymore).

The lighting device (“device”) comprises: (a) a light source configured to provide blue light source light, (b) a layer of a first luminescent material (“green/yellow luminescent material”) configured to convert at least part of the light source light into first luminescent material light with light intensity in one or more of the green spectral region (“in the green”) and yellow spectral region (“in the yellow”), (c) a layer of a second luminescent material (“red luminescent material”) configured to convert at least part of the light source light into second luminescent material light with light intensity in the red spectral region (“in the red”), wherein the light source is covered by the layer of the second luminescent material, followed by the layer of the first luminescent material, wherein the integrated spectral overlap between the absorption curve of the second luminescent material with the emission spectrum of the light source light is at least four times larger than the integrated spectral overlap between the absorption curve of the second luminescent material with the emission spectrum of the first luminescent material, (d) a light exit face (or “light outcoupling face”), wherein the lighting device is configured to provide lighting device light (“device light”) downstream from said light exit face, wherein the lighting device light comprises one or more of said light source light, said first luminescent material light, and said second luminescent material light, and wherein the second luminescent material is configured to be at least partly saturated with light source light at or above at least 50% of nominal operation power of the lighting device.

Published international patent application WO 2010/116294 A1 discloses a luminescent converter for a phosphor-enhanced light source. The luminescent converter comprises a first luminescent material configured for absorbing at least a part of excitation light emitted by a light emitter of the phosphor-enhanced light source, and for converting at least a part of the absorbed excitation light into first emission light comprising a longer wavelength compared to the excitation light. The luminescent converter further comprises a second luminescent material comprising organic luminescent material and configured for absorbing at least a part of the first emission light emitted by the first luminescent material, and for converting at least a part of the absorbed first emission light into second emission light having a longer wavelength compared to the first emission light.

Especially, such lighting device may be used for providing lighting device light, especially white lighting device light, that is tunable in color temperature and that especially may substantially follow the black body locus with increasing or decreasing power to the light source. Such lighting device does not need complicated electronics. Further, pulse-width modulation is not necessary, though in an embodiment pulse-width modulation is applied. However, in other embodiments pulse-width modulation is not applied, and intensity tuning may substantially only be achieved by controlling the power provided to the light source (without tuning a pulse width). Further, in embodiments also no AC LED is applied. Hence, with the invention DC LEDs without pulse-width modulation may be applied.

Preferably, the light source is a light source that during operation emits (light source light) at least light at a wavelength selected from the range of 400-495 nm, even more especially in the range of 440-490 nm. Hence, in a specific embodiment, the light source is configured to generate blue light. The blue light may e.g. be generated by a luminescent material comprising light source, such as a pc LED (phosphor converter LED), or by a LED not comprising a phosphor, but wherein the LED itself is configured to provide blue light. Hence, in a specific embodiment, the light source comprises a solid state LED light source (such as a LED or laser diode). The term “light source” may also relate to a plurality of light sources, such as 2-20 (solid state) LED light sources. Hence, the term LED may also refer to a plurality of LEDs. The term “light source” may also relate to a plurality of different light sources, each having a dominant wavelength within the range of 440-490 nm.

The lighting device may especially be configured to provide at one or more operation powers white light, especially in embodiments over the (entire) range of 50-100% of the nominal power. Hence, the lighting device may be configured to provide white light. However, this does not exclude that the lighting device may also be able to provide colored light. However, especially the lighting device is configured to provide white light, even more especially different types of white light in dependence of the operation power.

The term white light herein, is known to the person skilled in the art. It especially relates to light having a correlated color temperature (CCT) between about 2000 and 20000 K, especially 2700-20000 K, for general lighting especially in the range of about 2700 K and 6500 K, and for backlighting purposes especially in the range of about 7000 K and 20000 K, and especially within about 15 SDCM (standard deviation of color matching) from the BBL (black body locus), especially within about 10 SDCM from the BBL, even more especially within about 5 SDCM from the BBL. In an embodiment, the lighting device may be configured to provide white light having a correlated color temperature (CCT) between about 2000 and 20000 K, such as 2000-10000 K, like 2000-6000 K.

The lighting device is especially based on the principle of two, three, or more bands. In specific embodiments, the light source and first luminescent material may be configured to provide white light, with the second luminescent material substantially only be used to tune the color temperature. In such embodiments, the lighting device may essentially be based on the two band principle (YB (yellow-blue)) but including a third red band. The invention may also be based on the tri-band principle, with RGB, with red, green and blue, provided by the second luminescent material, the first luminescent material, and the light source, respectively. Further, also combinations are possible, as the first luminescent material may e.g. also be configured to provide green and yellow luminescent material light. Especially however, the lighting device described herein comprises a first luminescent material that is configured to provide yellow first luminescent material light. The second luminescent material is especially configured to provide within the visible spectrum only red luminescent material light. The term “first luminescent material” or “second luminescent material” may each independently refer to a plurality of different luminescent materials (each complying with the herein indicated conditions).

The terms “violet light” or “violet emission” especially relates to light having a wavelength in the range of about 380-440 nm. The terms “blue light” or “blue emission” especially relates to light having a wavelength in the range of about 440-495 nm (including some violet and cyan hues). The terms “green light” or “green emission” especially relate to light having a wavelength in the range of about 495-570 nm. The terms “yellow light” or “yellow emission” especially relate to light having a wavelength in the range of about 570-590 nm. The terms “orange light” or “orange emission” especially relate to light having a wavelength in the range of about 590-620 nm. The terms “red light” or “red emission” especially relate to light having a wavelength in the range of about 620-780 nm. The term “pink light” or “pink emission” refers to light having a blue and a red component. The terms “visible”, “visible light” or “visible emission” refer to light having a wavelength in the range of about 380-780 nm.

The phrase, “light intensity in one or more of the green spectral region and yellow spectral region” especially indicates that the respective luminescent material provides, upon excitation (with the blue light) emission intensity in the green and/or yellow part of the spectrum. Even more especially, the luminescence has a dominant wavelength in the green or yellow. Likewise, the phrase “light intensity in the red spectral region” especially indicates that the respective luminescent material provides, upon excitation (with the blue light and/or yellow and/or green light) emission intensity in the red part of the spectrum. Even more especially, the luminescence has a dominant wavelength in the red. Likewise, this may apply to similar phrases. Hence, a red luminescent material may especially be perceived as red, and a green luminescent material may especially be perceived as green, etc. Further, the first luminescent material and second luminescent materials are different luminescent material (see also the examples provided herein).

Especially, the first and second luminescent material may be provided as separate layers or as mixtures within a single layer. The luminescent materials may also be provided at different locations within the device. In a specific embodiment, the light source comprises a solid state light source comprising a light exit surface ((LED) die), wherein the lighting device further comprises a converter element configured downstream from the light exit surface, wherein the converter element comprises the first luminescent material and the second luminescent material, and wherein optionally the converter element further comprises said light exit face. The converter may comprise a single layer or a plurality of layers.

Especially, the (first) luminescent material may comprise a M₃A₅O₁₂:Ce³⁺ (second) luminescent material, wherein M is selected from the group consisting of Sc, Y, Tb, Gd, and Lu, wherein A is selected from the group consisting of Al, Ga, Sc and In. Preferably, M at least comprises one or more of Y and Lu, and wherein A at least comprises Al and/or Ga. These types of materials may give highest efficiencies. Embodiments of garnets especially include M₃A₅O₁₂ garnets, wherein M comprises at least yttrium and/or lutetium and wherein A comprises at least aluminum. Such garnet may be doped with cerium (Ce), with praseodymium (Pr) or a combination of cerium and praseodymium; especially however with Ce. Especially, A comprises aluminum (Al), however, A may also partly comprise gallium (Ga) and/or scandium (Sc) and/or indium (In), especially up to about 20% of Al, more especially up to about 10% of Al (i.e. the A ions essentially consist of 90 or more mole % of Al and 10 or less mole % of one or more of Ga, Sc and In); A may especially comprise up to about 10% gallium. In another variant, A and O may at least partly be replaced by Si and N. The element M may especially be selected from the group consisting of yttrium (Y), gadolinium (Gd), terbium (Tb) and lutetium (Lu). Further, Gd and/or Tb are especially only present up to an amount of about 20% of M. In a specific embodiment, the garnet (second) luminescent material comprises (Y₁₋ₓLuₓ)₃B₅O₁₂:Ce, wherein x is equal to or larger than 0 and equal to or smaller than 1. The term “:Ce” or “:Ce³⁺”, indicates that part of the metal ions (i.e. in the garnets: part of the “M” ions) in the (second) luminescent material is replaced by Ce. For instance, assuming (Y₁₋ₓLuₓ)₃Al₅O₁₂:Ce, part of Y and/or Lu is replaced by Ce. This notation is known to the person skilled in the art. Ce will replace M in general for not more than 10%; in general, the Ce concentration will be in the range of 0.1-4%, especially 0.1-2% (relative to M). Assuming 1% Ce and 10% Y, the full correct formula could be (Y_{0.1}Lu_{0.89}Ce_{0.01})₃Al₅O₁₂. Ce in garnets is substantially or only in the trivalent state, as known to the person skilled in the art. The term “YAG” especially refers to M=Y and A=Al; the term “LuAG” especially refers to M=Lu and A=Al.

The first luminescent material is especially configured to absorb at least part of the light source light and convert into first luminescent material light (which is green and/or yellow). The second luminescent material is especially configured to absorb at least part of the light source light and configured (this absorbed light) into second luminescent material light (which is red). Hence, the second luminescent material has absorptions in the blue. The first luminescent material and second luminescent materials are herein together also indicated as “luminescent materials”.

The lighting device comprises a light exit surface. This may be the downstream face of a window comprising one or more of the luminescent materials and/or comprising one or more of the luminescent materials at an upstream side of the window, such as a coating to the upstream face of the window. Also combinations of such embodiments are possible. For instance, the window may comprise a light transmissive material, such as a light transmissive polymeric material, like PMMA, or a ceramic material. Hence, the window (material) may comprises one or more materials selected from the group consisting of a transmissive organic material, such as selected from the group consisting of PE (polyethylene), PP (polypropylene), PEN (polyethylene napthalate), PC (polycarbonate), polymethylacrylate (PMA), polymethylmethacrylate (PMMA) (Plexiglas or Perspex), cellulose acetate butyrate (CAB), silicone, polyvinylchloride (PVC), polyethylene terephthalate (PET), including in an embodiment (PETG) (glycol modified polyethylene terephthalate), PDMS (polydimethylsiloxane), and COC (cyclo olefin copolymer). Especially, the window may comprise an aromatic polyester, or a copolymer thereof, such as e.g. polycarbonate (PC), poly (methyl)methacrylate (P(M)MA), polyglycolide or polyglycolic acid (PGA), polylactic acid (PLA), polycaprolactone (PCL), polyethylene adipate (PEA), polyhydroxy alkanoate (PHA), polyhydroxy butyrate (PHB), poly(3-hydroxybutyrate-co-3-hydroxyvalerate) (PHBV), polyethylene terephthalate (PET), polybutylene terephthalate (PBT), polytrimethylene terephthalate (PTT), polyethylene naphthalate (PEN); especially, the window may comprise polyethylene terephthalate (PET). Hence, the window is especially a polymeric material. However, in another embodiment the window (material) may comprise an inorganic material. Preferred inorganic materials are selected from the group consisting of glasses, (fused) quartz, transmissive ceramic materials, and silicones. Also hybrid materials, comprising both inorganic and organic parts may be applied. Especially preferred are PMMA, transparent PC, or glass as material for the window.

The terms “upstream” and “downstream” relate to an arrangement of items or features relative to the propagation of the light from a light generating means (here the especially the first light source), wherein relative to a first position within a beam of light from the light generating means, a second position in the beam of light closer to the light generating means is “upstream”, and a third position within the beam of light further away from the light generating means is “downstream”.

The light exit face (of the lighting device) is herein also indicated as “light outcoupling face”. Especially, the lighting device is configured to provide lighting device light (“device light”) downstream from said light exit face. This light may be perceived by a user. Optionally, downstream from the window optics may be configured, such as beam shaping optics. The lighting device light comprises one or more of said light source light, said first luminescent material light, and said second luminescent material light. As indicated above, especially the lighting device light comprises white light, with variable color temperature. Hence, in embodiments, and dependent e.g. upon the power during operation, the lighting device light comprises said light source light, said first luminescent material light, and optionally said second luminescent material light.

However, in other embodiments, and dependent e.g. upon the power during operation, the lighting device light comprises said light source light, said first luminescent material light, and said second luminescent material light. Especially, over substantially the entire power (watt) range of the lighting device the lighting device light comprises said light source light, said first luminescent material light, and said second luminescent material light (with, dependent upon the power during operation, different relative contributions of second luminescent material light (and optionally also first luminescent material light (see also below))).

Especially, during operation of the lighting device the second luminescent material may at least partially be saturated. Saturation of luminescent materials is known in the art, and is especially of relevance for luminescent materials having a relative long decay time τ (i.e. radiative decay time). Hence, herein especially the second luminescent material has a decay time τᵣ of at least 1 ms, like in the range of 1-500 ms, such as at least 2 ms, like at least 4 ms, such as at least 6 ms, like at least 10 ms. During a saturation process, the fraction of the excitation radiation converted by the luminescent material into luminescent material light decreases compared to the situation in which no saturation occurs. As known in the art, saturation may be achieved as function of e.g. the activator concentration as well as the offered light source intensity. The activator concentration or luminescent center concentration may be tuned by the person skilled in the art. Herein, activators are especially divalent europium, trivalent cerium or tetravalent manganese.

During operation of the lighting device the first luminescent material may at least partially be saturated. Saturation of luminescent materials is known in the art, and is especially of relevance for luminescent materials having a relative long decay time τ (i.e. radiative decay time). Hence, herein especially the second luminescent material has a decay time τᵣ of at least 1 ms, for example in the range of 1-500 ms, or preferably at least 2 ms, for example in the range of 2-500 ms, more preferably at least 4 ms, for example in the range of 4-100 ms, even more preferably at least 6 ms, for example in the range of 6-500 ms, yet even more preferably at least 10 ms, for example in the range of 10-500 ms.

The ratio between the decay time of the first luminescent material (210) τ_{y} and the decay time of the second luminescent material (220) τᵣ is in the range of 0.1<τ_{y}/τᵣ<0.8. In another preferred embodiment, the ratio between the decay time of the first luminescent material (210) τ_{y} and the decay time of the second luminescent material (220) τᵣ is in the range of 0.2<τ_{y}/τᵣ<0.6. In yet another preferred embodiment, the ratio between the decay time of the first luminescent material (210) τ_{y} and the decay time of the second luminescent material (220) τᵣ is in the range of 0.3<τ_{y}/τᵣ<0.5.

Herein, it is indicated that the luminescent material may at last partly be saturated. This implies that a part of all luminescent centers may be saturated (see e.g. also WO2007020556). The excitation light penetrates the luminescent material (layer) and for instance luminescent material closer to the light source may have a higher change of saturation than more remote from the light source. Hence, for the effect of the invention, not all second luminescent material light is necessarily saturated, though optionally this may be the case (at nominal power). Further, it is herein indicated that at or above at least 50% of nominal operation power of the lighting device the second luminescent material is saturated. This implies that at powers of 50% of nominal up to 100% nominal power at least part of the luminescent material is saturated. In the range of 0-50% of nominal power, the luminescent material may also be partly saturated, but this is not necessarily the case. However, in a specific embodiment the second luminescent material is configured to be at least partly saturated with (i) light source light, or (ii) light source light and first luminescent material light, at or above at least 30% of nominal operation power of the lighting device. Especially however, in the range of up to 10%, such as up to 20% of the nominal power, the second luminescent material is not saturated. With these ranges, at low power a low color temperature may be achieved, whereas as at higher powers saturation increases; the higher the power, the higher the saturation, and thus the higher the color temperature. Advantageously, this is an intuitive process comparable to conventional incandescent lamps.

The phrase “at or above at least 50% of nominal operation power of the lighting device the luminescent material is saturated” and similar phrases indicate especially that when increasing the power from off to maximum power, at the indicated value (here 50% of the nominal power) the indicated luminescent material starts to saturate and will keep being saturated the whole range up to (and of course including) 100%. Below the indicated value, the luminescent material may not (at least partly) be saturated. Hence, over the entire range of the indicated value (here 50% of the nominal power) up to 100% (of the nominal power) the luminescent material is at least partly saturated. Hence, the phrase “at or above at least 30% of nominal operation power of the lighting device the luminescent material is saturated” especially indicates that over the entire range of the indicated value (here 30% of the nominal power) up to 100% (of the nominal power) the luminescent material is at least partly saturated.

The phrase “in the range of up to 10% of the nominal power, the luminescent material is not saturated” and similar phrases especially indicate that when increasing the power from off to at least the indicated value (here 10% of the nominal power) of the maximum power no luminescent material is saturated. Hence, over the entire range of 0 (i.e. “off”) to the indicated power (here 10% of the nominal power), the relevant luminescent material is not saturated.

As indicated herein, saturation may differ from luminescent material to luminescent material (used in the herein described device).

A combination of luminescent materials of which one of the luminescent materials is not saturated at low power but saturated at high power will especially show a color shift with increasing power with the relative contribution of the saturating luminescent material decreasing with increasing power.

As indicated above, the second luminescent material is configured to absorb at least part of the light source light and optionally also at least part of the first luminescent material light. Hence, the second luminescent material is configured to be at least partly saturated with (i) light source light, or (ii) light source light and first luminescent material light. In a specific embodiment, the second luminescent material is configured to be at least partly saturated with (ii) light source light and first luminescent material light, at or above at least 50% of nominal operation power of the lighting device. In other words, the second luminescent material is configured to absorb (also) at least part of the first luminescent material light.

The term “nominal operation” especially indicates the power for which the lighting device is designed. Hence, a 5 W LED device has 5 Watt nominal power.

A very useful red luminescent material appeared to be a Mn(IV) type luminescent material. Hence, in an embodiment the second luminescent material comprises a red luminescent material selected from the group consisting of Mn(IV) luminescent materials, even more especially the second luminescent material comprises a luminescent material of the type M₂AX₆ doped with tetravalent manganese, wherein M comprises an alkaline cation, wherein A comprises a tetravalent cation, and wherein X comprises a monovalent anion, at least comprising fluorine (F). For instance, M₂AX₆ may comprise K_{1.5}Rb_{0.5}AX₆. M relates to monovalent cations, such as selected from the group consisting of potassium (K), rubidium (Rb), lithium (Li), sodium (Na), cesium (Cs) and ammonium (NH₄⁺), and especially M comprises at least one or more of K and Rb. Preferably, at least 80%, even more preferably at least 90%, such as 95% of M consists of potassium and/or rubidium. The cation A may comprise one or more of silicon (Si) titanium (Ti), germanium (Ge), stannum (Sn) and zinc (Zn). Preferably, at least 80%, even more preferably at least 90%, such as at least 95% of M consists of silicon and/or titanium. Especially, M comprises potassium and A comprises titanium. X relates to a monovalent anion, but especially at least comprises fluorine. Other monovalent anions that may optionally be present may be selected from the group consisting of chlorine (Cl), bromine (Br), and iodine (I). Preferably, at least 80%, even more preferably at least 90%, such as 95% of X consists of fluorine. The term “tetravalent manganese” refers to Mn⁴⁺. This is a well-known luminescent ion. In the formula as indicated above, part of the tetravalent cation A (such as Si) is being replaced by manganese. Hence, M₂AX₆ doped with tetravalent manganese may also be indicated as M₂A₁₋ₘMnₘX₆. The mole percentage of manganese, i.e. the percentage it replaces the tetravalent cation A will in general be in the range of 0.1-15%, especially 1-12%, i.e. m is in the range of 0.001-0.15, especially in the range of 0.01-0.12. Further embodiments may be derived from WO2013/088313, which is herein incorporated by reference. However, also other red luminescent materials may be applied. Hence, in an embodiment the second luminescent material comprises M₂AX₆ doped with tetravalent manganese, wherein M comprises an alkaline cation, wherein A comprises a tetravalent cation, and wherein X comprises a monovalent anion, at least comprising fluorine. Even more especially, wherein M comprises at least one or more of K and Rb, wherein A comprises one or more of Si and Ti, and wherein X=F.

Especially, in this invention the second luminescent material reaches to at least some extend into saturation at high powers. However, optionally this may also apply to the first luminescent material. Hence, in some embodiments the first luminescent material may also have a relative long decay time. Therefore, in a further specific embodiment the first luminescent material is configured to be at least partly saturated with light source light at or above at least 50% of nominal operation power of the lighting device. In yet a further specific embodiment, the first luminescent material comprises M₃A₅O₁₂:Ce³⁺, wherein M is selected from the group consisting of Sc, Y, Tb, Gd, and Lu, wherein A is selected from the group consisting of Al, Ga, Sc and In, wherein M at least comprises Gd and wherein A at least comprises Al and Ga. Especially, the first luminescent material has a relatively long decay time in the green and the second luminescent material has a relatively short decay time in the red. In a specific embodiment, M₃A₅O₁₂:Ce³⁺ comprises Gd₃(Al,Ga)₅O₁₂:Ce³⁺. These specific types of garnets surprisingly appear to be a long decay luminescent material, especially Gd₃(Al_{1-y}G_{y})₅O₁₂:Ce³⁺, with y especially in the range of 0.1-0.9, such as 0.2-0.8, such as 0.3-0.7, like e.g. Gd₃Al₂G₃O₁₂:Ce³′. Especially, the first luminescent material may be configured to be saturated at 50% nominal power or higher when the second luminescent material does substantially not absorb green and/or yellow luminescence. Hence, in embodiment the second luminescent material may be configured to substantially only absorb light source light and substantially no first luminescent material light. Therefore, in an embodiment the first luminescent material is configured to be at least partly saturated with substantially only light source light. Hence, in an embodiment the second luminescent material has an absorption in the blue that is at least 2 times higher, especially at least 5 times higher, than in the green and/or yellow, especially in the green and yellow. Especially, the absorption of the first luminescent material light (by the second luminescent material) is substantially smaller than the absorption of the light source light (by the second luminescent material). Especially, the integrated spectral overlap between the absorption curve of the second luminescent material with the emission spectrum of the light source light (in the blue) is at least four times larger than the integrated spectral overlap between the absorption curve of the second luminescent material with the emission spectrum of the first luminescent material (i.e. the first luminescent material light), especially at least 5 time larger, more especially at least 10 time larger, such as even more especially at least 20 times larger. In these embodiment, especially the first luminescent material has a decay time of at least 1 ms, like in the range of 1-500 ms, such as at least 2 ms, like at least 4 ms, such as at least 6 ms, like at least 10 ms. In a specific embodiment the first luminescent material is configured to be at least partly saturated with (i) light source light, at or above at least 30% of nominal operation power of the lighting device. Especially however, in the range of up to 10%, such as up to 20% of the nominal power, the first luminescent material is not saturated.

In yet a further embodiment the lighting device may further comprise a control system configured to control the power provided to the light source. Alternatively or additionally, the control system may be external from the lighting device. Optionally, the control system may comprise a plurality of elements, of which some may be comprised by the lighting device and others may be external from the lighting device (such as a remote user interface, see also below). Optionally, also the power may be included in the lighting device, such as in the case of certain handheld flash lights. The lighting device may e.g. be integrated in a lighting system with a plurality of lighting device and optional other type of lighting devices than described herein.

In yet a further specific embodiment, the control system is configured to control the power provided to the light source as function of an input signal of a user interface. This user interface may be integrated in the lighting device, but may also be remote from the lighting device. Hence, the user interface may in embodiments be integrated in the lighting device but may in other embodiments be separate from the lighting device. The user interface may e.g. be a graphical user interface. Further, the user interface may be provided by an App for a Smartphone or other type of android device. Therefore, the invention also provides a computer program product, optionally implemented on a record carrier (storage medium), which when run on a computer executes the method as described herein (see below) and/or can control (the color temperature of the lighting device light of) the lighting device as described herein (as function of the power provided to the light source).

Alternatively or additionally, the control system is configured to control the power provided to the light source as function of one or more of a sensor signal and a timer. For instance, the lighting device may automatically follow the color temperature changes daylight during the day. To this end, a timer and/or a sensor may be used. However, a timer and/or a sensor may also be used for other purposes. For instance, the timer may be used to switch off after a predetermined time. Further, for instance the sensor may be a motion sensor, configured to sense motion, with the control system configured to switch on the lighting device when the motion sensor senses motion or presence of e.g. a person.

As indicated above, the invention also provides a method for providing white light with a tunable color temperature, wherein the method comprises providing white lighting device light with the lighting device as defined herein and controlling the color temperature as function of the power provided to the light source. Especially, the color temperature is controlled as function of one or more of an input signal of a user interface, a sensor signal and a timer (see also above).

The lighting device may be part of or may be applied in e.g. office lighting systems, household application systems, shop lighting systems, home lighting systems, accent lighting systems, spot lighting systems, theater lighting systems, fiber-optics application systems, projection systems, self-lit display systems, pixelated display systems, segmented display systems, warning sign systems, medical lighting application systems, indicator sign systems, decorative lighting systems, portable systems, automotive applications, green house lighting systems, horticulture lighting, or LCD backlighting.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 shows color points of (dimmed) halogen lamp (black open circles) and color points of LEDs with slow red phosphor (with indicated decay time) a same relative intensity; the squares indicate a decay time of 8 ms and the triangles indicate a decay time of 12 ms for the second luminescent material (red);

FIG. 2 shows color points as a function of the LED drive condition for a device with the Blue-Red-Yellow structure, wherein both the first luminescent material and second luminescent material can be brought into saturation;

FIGS. 3a-3c schematically depicts some aspects of the invention.

The schematic drawings are not necessarily on scale.

### DETAILED DESCRIPTION OF THE EMBODIMENTS

In an embodiment, a blue LED is covered with a mixture of phosphors. A ‘normal’ yellow phosphor is used in combination with a slow red phosphor. The red phosphor has a broad excitation spectrum (absorbing both blue and yellow/green) and a long decay time. The decay time of the red phosphor should be chosen such that at nominal drive condition of the LED a considerable part of the red-phosphor is saturated, e.g. 30-90%.

Dimming a halogen bulb will lead to color point on the BBL, varying between 3000K (100% intensity) and 2200K (3% intensity). At intermediate CCT's the light output of the halogen bulb varies between these two levels.

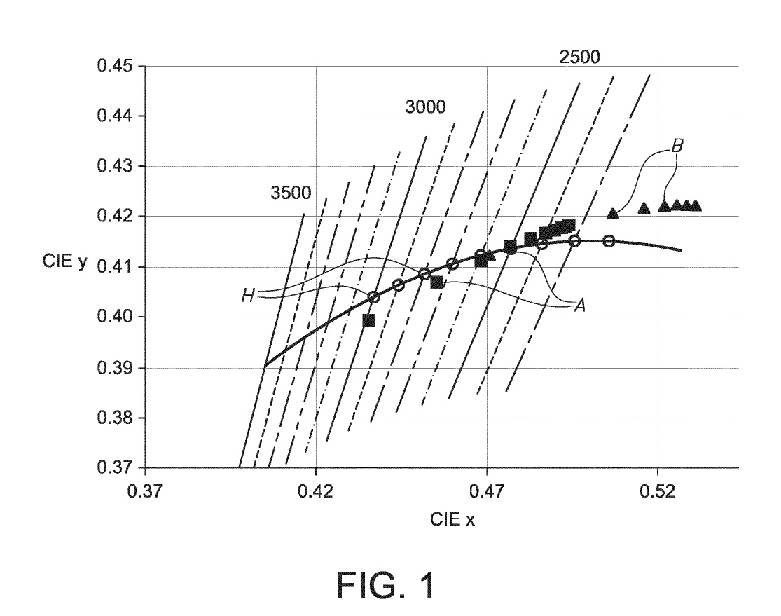

The color point of a LED device with a slow red phosphor was calculated at these light levels (9 steps). A perfect device would yield a color point on the BBL, with 100K spacing. The results of these simulations are given in FIG. 1. The decay time determines the CCT range that can be made; in case the decay time is <<1 ms, the CCT-range is 0, for a decay time of 8 ms the CCT range is approximately 700K, for a decay time of 12 ms the CCT range becomes ˜1100K. The 8 ms decay time data are squares, indicated with A; the 12 ms decay data are triagles and are indicated with B. Halogen lamp data follow very well the BBL and are indicated with H. The values 2500-3500 indicate color temperatures in Kelvin.

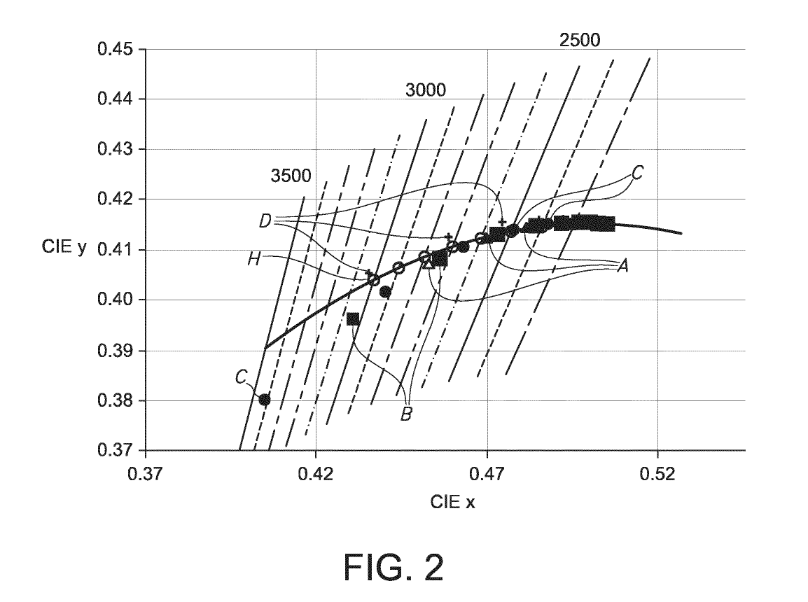

In an embodiment, a blue LED is covered with 2 layers of phosphor. Both phosphors, the first luminescent material (yellow/green) and the second luminescent material (red) have a long decay time. Both the yellow and the red phosphor only absorb blue light. The Blue LED is covered by a red phosphor layer, followed by a yellow phosphor layer (BRY structure). The decay time of the yellow and the red phosphor should be chosen such that at nominal drive condition of the LED a considerable part of the phosphors is saturated, e.g. 40%. With the proper decay times for the yellow and red phosphor, the color point variation upon dimming can be following the BBL as shown in FIG. 2. Here, the references indicate the following:

| | | Decay time red | Decay time yellow |
|---|---|---|---|
| | | luminescent | luminescent |
| | Symbol | material (ms) | material (ms) |
| A | Triangle | 6 | 6 |
| B | Solid square | 8 | 8 |
| C | Circle (grey) | 10 | 10 |
| D | + | 8 | 7 |
| H | Open circle | | |

Hence, the invention shows that when using a slow red phosphor (decay time several ms), the amount of red in the emission spectrum of the LED is determined by the light intensity of the source. If the red phosphor in addition has a broad absorption spectrum, the color point follows the BBL. If the LED is used at nominal current, the amount of red light in the spectrum is decreased due to saturation of the red phosphor; dimming the LED leads to decreased saturation of the red phosphor (apparent thickness of the red phosphor layer increases), resulting in light with a lower CCT. Due to the broad excitation spectrum the light generated will be close to the BBL.

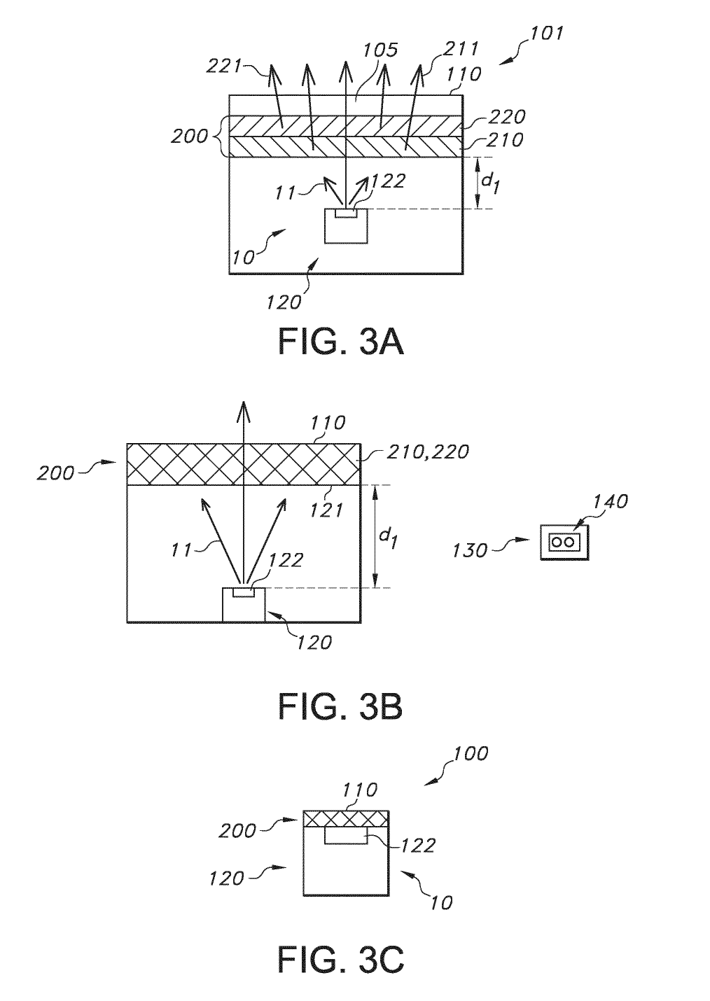

FIG. 3a schematically depicts an embodiment of a lighting device 100 as described herein. The lighting device 100 comprises a light source 10 configured to provide blue light source light 11, a first luminescent material 210 configured to convert at least part of the light source light 11 into first luminescent material light 211 with light intensity in one or more of the green spectral region and yellow spectral region and a second luminescent material 220 configured to convert at least part of the light source light 11 into second luminescent material light 221 with light intensity in the red spectral region.

Further, the lighting device comprises a light exit face 110. Herein in the embodiment of FIG. 3a, this may be the downstream face of a window 105. In FIG. 3b this is the downstream face of a converter 200. Here, in FIGS. 3a-3c the converter 200 comprises the first luminescent material 210 and the second luminescent material 220, e.g. a layers (FIG. 3a), or as mixture (FIGS. 3b-3c). Note that the converter 200 may also include materials and/or layers other than the first luminescent material 210 and the second luminescent material 220. In FIG. 3a, the converter is configured upstream of the light exit face, here upstream of window 105. Especially, when using separate layers of the first luminescent material 210 and the second luminescent material 220, the latter is configured downstream of the former, in order to further facilitate absorption of the first luminescent material light 211. Would the second luminescent material 220 substantially not absorb first luminescent material light 211, then the order of the layers may also be revered. Further, also mixtures may be applied (see FIGS. 3b-3c).

Further, the lighting device 100 is configured to provide lighting device light 101 downstream from said light exit face 110. Here, as shown in FIG. 3a, the lighting device light 101 comprises one or more of said light source light 11, said first luminescent material light 211, and said second luminescent material light 221. As indicated above, the second luminescent material 220 is configured to be at least partly saturated with light source light 11 at or above at least 50% of nominal operation power of the lighting device 100.

The distance between the first and/or the second luminescent materials is indicated with reference d1, which is (substantially) zero in the case of FIG. 3c (d1 not depicted in FIG. 3c) and which may be in the range of 0.1-50 mm, especially 1-20 mm in e.g. the embodiment of FIGS. 3a-3b. In the schematically depicted embodiment, the distance d1 is the distance between a light exit surface 122 of a solid state light source 120.

FIG. 3b schematically further depicts a control system 130, which may include a user interface 140.

The lighting device 100 may especially be applied for providing white lighting device light (101) that is tunable in color temperature and follows the black body locus with increasing or decreasing power to the light source (10).

The term “substantially” herein, such as in “substantially all light” or in “substantially consists”, will be understood by the person skilled in the art. The term “substantially” may also include embodiments with “entirely”, “completely”, “all”, etc. Hence, in embodiments the adjective substantially may also be removed. Where applicable, the term “substantially” may also relate to 90% or higher, such as 95% or higher, especially 99% or higher, even more especially 99.5% or higher, including 100%. The term “comprise” includes also embodiments wherein the term “comprises” means “consists of”. The term “and/or” especially relates to one or more of the items mentioned before and after “and/or”. For instance, a phrase “item 1 and/or item 2” and similar phrases may relate to one or more of item 1 and item 2. The term “comprising” may in an embodiment refer to “consisting of” but may in another embodiment also refer to “containing at least the defined species and optionally one or more other species”.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

The devices herein are amongst others described during operation. As will be clear to the person skilled in the art, the invention is not limited to methods of operation or devices in operation.

It should be noted that the above-mentioned embodiments illustrate rather than limit the invention, and that those skilled in the art will be able to design many alternative embodiments without departing from the scope of the appended claims. In the claims, any reference signs placed between parentheses shall not be construed as limiting the claim. Use of the verb “to comprise” and its conjugations does not exclude the presence of elements or steps other than those stated in a claim. The article “a” or “an” preceding an element does not exclude the presence of a plurality of such elements. The invention may be implemented by means of hardware comprising several distinct elements, and by means of a suitably programmed computer. In the device claim enumerating several means, several of these means may be embodied by one and the same item of hardware. The mere fact that certain measures are recited in mutually different dependent claims does not indicate that a combination of these measures cannot be used to advantage.

The invention further applies to a device comprising one or more of the characterizing features described in the description and/or shown in the attached drawings. The invention further pertains to a method or process comprising one or more of the characterizing features described in the description and/or shown in the attached drawings.

The various aspects discussed in this patent can be combined in order to provide additional advantages. Furthermore, some of the features can form the basis for one or more divisional applications.

1. A lighting device comprising:
a light source configured to provide blue light source light;
a layer of a first luminescent material configured to convert at least part of the light source light into first luminescent material light with light intensity in one or more of the green spectral region and yellow spectral region;
a layer of a second luminescent material configured to convert at least part of the light source light into second luminescent material light with light intensity in the red spectral region;
wherein the light source is covered by the layer of the second luminescent material, followed by the layer of the first luminescent material,
wherein the integrated spectral overlap between the absorption curve of the second luminescent material with the emission spectrum of the light source light is at least four times larger than the integrated spectral overlap between the absorption curve of the second luminescent material with the emission spectrum of the first luminescent material,
a light exit face;
wherein:
the lighting device is configured to provide lighting device light downstream from said light exit face, wherein the lighting device light comprises one or more of said light source light, said first luminescent material light, and said second luminescent material light;
wherein the second luminescent material is configured to be at least partly saturated with light source light at or above at least 50% of nominal operation power of the lighting device.

2. The lighting device according to claim 1, wherein the second luminescent material is configured to be at least partly saturated with light source light at or above at least 30% of nominal operation power of the lighting device.

3. The lighting device according to claim 1, wherein the second luminescent material has a decay time τᵣ of at least 1 ms, and the ratio between the decay time of the first luminescent material τ_{y} and the decay time of the second luminescent material τᵣ is in the range of 0.1<τ_{y}/τᵣ<0.8

4. The lighting device according claim 1, wherein the second luminescent material comprises M₂AX₆ doped with tetravalent manganese, wherein M comprises an alkaline cation, wherein A comprises a tetravalent cation, and wherein X comprises a monovalent anion, at least comprising fluorine.

5. The lighting device according to claim 4, wherein M comprises at least one or more of K and Rb, wherein A comprises one or more of Si and Ti, and wherein X=F.

6. The lighting device according to claim 1, wherein the first luminescent material comprises M₃A₆O₁₂:Ce³⁺, wherein M is selected from the group consisting of Sc, Y, Tb, Gd, and Lu, and wherein A is selected from the group consisting of Al, Ga, Sc and In.

7. The lighting device according to claim 1, wherein the integrated spectral overlap between the absorption curve of the second luminescent material with the emission spectrum of the light source light is at least five times larger than the integrated spectral overlap between the absorption curve of the second luminescent material with the emission spectrum of the first luminescent.

8. The lighting device according to claim 7, wherein M at least comprises Gd and wherein A at least comprises Al and Ga.

9. The lighting device according to claim 1, wherein the light source comprises a solid state light source comprising a light exit surface, wherein the lighting device further comprises a converter element configured downstream from the light exit surface, wherein the converter element comprises the layer of the first luminescent material and the layer of the second luminescent material, and wherein the converter element further comprises said light exit face.

10. The lighting device according to claim 1, further comprising a control system configured to control the power provided to the light source.

11. The lighting device according to claim 10, wherein the control system is configured to control the power provided to the light source as function of an input signal of a user interface.

12. The lighting device according to claim 10, wherein the control system is configured to control the power provided to the light source as function of one or more of a sensor signal and a timer.
